(19) United States
(12) Patent Application Publication
(10) Pub. No.: US 2022/0196705 A1
(43) Pub. Date: Jun. 23, 2022

(54) INSPECTION APPARATUS AND INSPECTION METHOD FOR ELECTRONIC DEVICE

(71) Applicant: Sumitomo Electric Industries, Ltd., Osaka (JP)

(72) Inventor: Mitsuharu HIRANO, Osaka-shi (JP)

(73) Assignee: Sumitomo Electric Industries, Ltd., Osaka (JP)

(21) Appl. No.: 17/524,629

(22) Filed: Nov. 11, 2021

(30) Foreign Application Priority Data
Dec. 17, 2020 (JP) 2020-209091

(51) Int. Cl. G01R 1/067; G01R 1/073; G01R 31/28; H04N 5/33; G01J 5/00

(52) U.S. Cl. CPC G01R 1/06794; G01R 1/073; G01R 31/2875; G01J 2005/0077; H04N 5/33; G01J 5/0096; G01R 31/2877

(57) ABSTRACT

An inspection apparatus for an electronic device is provided. The electronic device includes a substrate and an electrode located on the substrate. The inspection apparatus includes a support to support the electronic device, a probe to be brought into contact with a surface of the electrode, a temperature adjusting device configured to adjust at least one of a temperature of the surface of the electrode and a temperature of the probe such that the temperature of the surface of the electrode and the temperature of the probe are different from each other, and a temperature measuring device configured to measure the temperature of the surface of the electrode.

### CROSS REFERENCE TO RELATED APPLICATIONS

The present application is based upon and claims the benefit of the priority from Japanese patent application No. 2020-209091, filed on Dec. 17, 2020, which is hereby incorporated by reference in its entirety.

### TECHNICAL FIELD

The present disclosure relates to an inspection apparatus and a method for electronic device.

### BACKGROUND

Japanese Unexamined Patent Application Publication No. 2007-103860 discloses a method of detecting a contact trace by comparing an image before a probe is brought into contact with a surface of an electrode with an image after the probe is brought into contact with the surface of the electrode. A contact point between the probe and the surface of the electrode is observed by a camera.

### SUMMARY

The present disclosure provides an inspection apparatus for an electronic device. The electronic device includes a substrate and an electrode located on the substrate. The inspection apparatus includes a support to support the electronic device, a probe to be brought into contact with a surface of the electrode, a temperature adjusting device configured to adjust at least one of a temperature of the surface of the electrode and a temperature of the probe such that the temperature of the surface of the electrode and the temperature of the probe are different from each other, and a temperature measuring device configured to measure the temperature of the surface of the electrode.

The present disclosure also provides an inspection method for an electronic device. The electronic device includes a substrate and an electrode provided located on the substrate. The method includes adjusting at least one of a temperature of a surface of the electrode and a probe such that the temperature of the surface of the electrode and the temperature of the probe are different from each other, bringing the probe into contact with the surface of the electrode, measuring the temperature of the surface of the electrode after the adjusting and the bringing are performed, and determining whether a contact state between the probe and the surface of the electrode is good, based on a measurement result of the temperature of the surface of the electrode.

### BRIEF DESCRIPTION OF THE DRAWINGS

The foregoing and other purposes, aspects and advantages will be better understood from the following detailed description of a preferred embodiment of the invention with reference to the drawings.

FIG. 1 schematically illustrates inspection apparatus for electronic device according to an embodiment.

FIG. 2 is a plan view schematically illustrating an electronic device inspected by inspection apparatus for electronic device and a probe according to an embodiment.

FIG. 3 is a cross-sectional view taken along line of FIG. 2.

FIG. 4 is a flowchart illustrating an inspecting method for an electronic device according to an embodiment.

FIG. 5 schematically illustrates inspection apparatus for an electronic device according to an embodiment when the temperature of probe is adjusted.

FIG. 6 is a graph illustrating an example of a relationship between temperature and time of surface of an electrode.

### DETAILED DESCRIPTION

In the method in Japanese Unexamined Patent Application Publication No. 2007-103860, it may be difficult to observe the contact point between the probe and the surface of the electrode. For example, when a large number of probes come into contact with surfaces of a large number of electrodes, it is difficult to observe all contact points at one imaging angle. In addition, it is often difficult to determine whether a contact state is good or not from the image of the camera. For this reason, the inventor of the present disclosure studied a new method and an apparatus capable of determining whether the contact state between the probe and the surface of the electrode is good or not.

The present disclosure provides an inspection apparatus and an inspection method for an electronic device capable of determining whether a contact state between a probe and a surface of an electrode is good or not.

According to an aspect of the present disclosure, there is provided an inspection apparatus for an electronic device. The electronic device includes a substrate and an electrode located on the substrate. The inspection apparatus includes a support to support the electronic device, a probe to be brought into contact with a surface of the electrode, a temperature adjusting device configured to adjust at least one of a temperature of the surface of the electrode and a temperature of the probe such that the temperature of the surface of the electrode and the temperature of the probe are different from each other, and a temperature measuring device configured to measure the temperature of the surface of the electrode.

According to the above inspection apparatus, in case the contact state between the probe and the surface of the electrode is good, the temperature of the surface of the electrode approaches the temperature of the probe due to heat transfer. On the other hand, in case the contact state between the probe and the surface of the electrode is poor, the temperature of the surface of the electrode does not approach the temperature of the probe. Therefore, by measuring the temperature of the surface of the electrode, it is possible to determine whether the contact state between the probe and the surface of the electrode is good or poor.

The temperature measuring device may include a thermographic camera. In this case, the temperature of the surface of the electrode can be measured in a non-contact manner. Further, the temperature of each surface of the plurality of electrodes can be measured simultaneously.

The inspection apparatus may further include a determination apparatus configured to determine whether a contact state between the probe and the surface of the electrode is good, based on a measurement result obtained by temperature measuring device. In this case, whether or not the contact state between the probe and the surface of the electrode is good can be determined by determination apparatus.

An inspection method according to another aspect of the present disclosure, there is provided an inspection method for an electronic device. The electronic device includes a substrate and an electrode provided located on the substrate. The method includes adjusting at least one of a temperature of a surface of the electrode and a probe such that the temperature of the surface of the electrode and the temperature of the probe are different from each other, bringing the probe into contact with the surface of the electrode, measuring the temperature of the surface of the electrode after the adjusting and the bringing are performed, and determining whether a contact state between the probe and the surface of the electrode is good, based on a measurement result of the temperature of the surface of the electrode.

According to the above inspection method, in case the contact state between the probe and the surface of the electrode is good, the temperature of the surface of the electrode approaches the temperature of the probe due to heat transfer. On the other hand, in case the contact state between the probe and the surface of the electrode is poor, the temperature of the surface of the electrode does not approach the temperature of the probe. Therefore, by measuring the temperature of the surface of the electrode, it is possible to determine whether the contact state between the probe and the surface of the electrode is good or not.

The bringing may be performed after the adjusting is performed. In this case, whether or not the contact state between the probe and the surface of the electrode is good can be determined in a short time after the probe being brought into contact with the surface of the electrode.

The inspection method may further include inspecting an electrical characteristic of the electronic device in a case where it is determined that the contact state between the probe and the surface of the electrode is good. In this case, the electrical characteristic of the electronic device can be inspected in a state in which the contact state between the probe and the surface of the electrode is good.

Hereinafter, embodiments of the present disclosure will be described in detail with reference to the accompanying drawings. In the description of the drawings, the same reference numerals are used for the same or equivalent elements, and redundant description is omitted. In the drawings, an XYZ orthogonal coordinate system is shown as necessary.

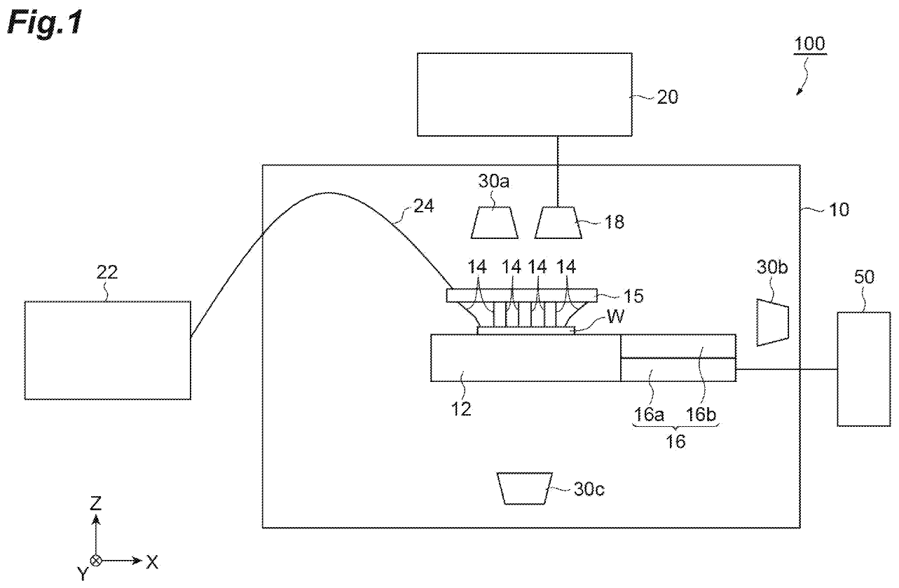

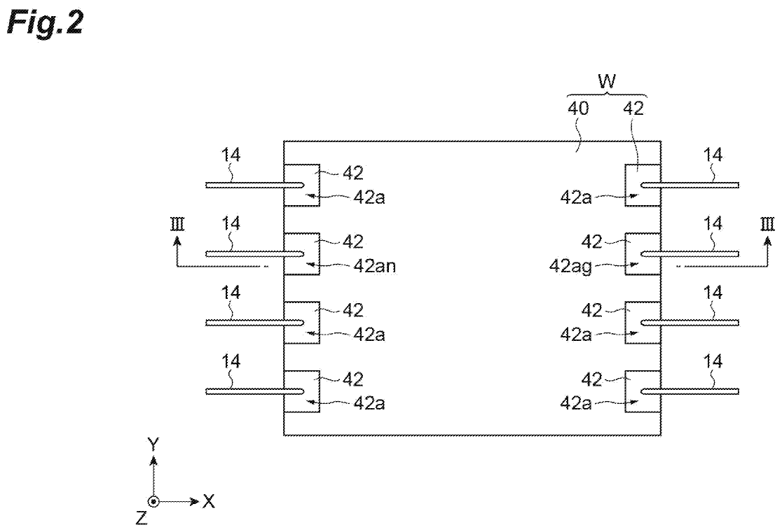

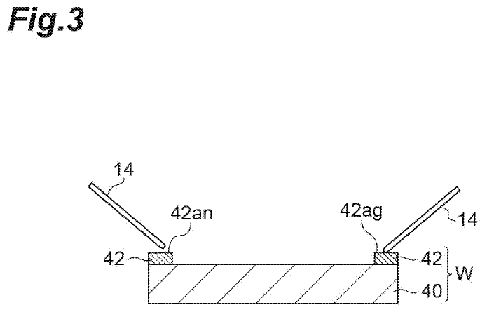

FIG. 1 schematically illustrates an inspection apparatus for an electronic device according to an embodiment. FIG. 2 is a plan view schematically illustrating the electronic device inspected by the inspection apparatus for the electronic device and a probe according to the embodiment. FIG. 3 is a cross-sectional view taken along line of FIG. 2. An inspection apparatus 100 for an electronic device W shown in FIG. 1 is, for example, a semiconductor test apparatus. Inspection apparatus 100 may inspect one or more electrical characteristics of electronic device W.

As shown in FIG. 2, electronic device W includes a substrate 40 and an electrode 42 provided on substrate 40. Electronic device W may be a semiconductor device or a printed wiring board. Substrate 40 may be a semiconductor substrate such as a silicon substrate or an insulating substrate. Electronic device W may include a plurality of electrodes 42. The number of electrodes 42 may be 100 or more. Electrode 42 is, for example, an electrode pad. Electrode 42 includes a metal such as aluminum or gold. A surface 42a of electrode 42 may have a rectangular shape, a circular shape, or a polygonal shape. A dimension of surface 42a of electrode 42 may be 10 μm or more and 1000 μm or less. When surface 42a of electrode 42 has a rectangular shape, the dimension of surface 42a of electrode 42 is a length of one side of the rectangle. When surface 42a of electrode 42 has a circular shape, the dimension of surface 42a of electrode 42 is a diameter of the circle. When surface 42a of electrode 42 has a polygonal shape, the dimension of surface 42a of electrode 42 is a diameter of a circumscribed circle of the polygon. A pitch between adjacent electrodes 42 may be 10 μm or more and 1000 μm or less. The pitch is a distance between centers of surfaces 42a of adjacent electrodes 42.

Inspection apparatus 100 comprises a prober 10. Prober 10 includes a support 12, a probe 14, a temperature adjusting device 16, and a temperature measuring device 18. Inspection apparatus 100 may comprise a determination device 20.

Support 12 supports electronic device W. Support 12 is, for example, an electrostatic chuck. Support 12 and probe 14 may be movable relative to each other. For example, support 12 is movable relative to probe 14. Support 12 may be movable in the X-axis direction, the Y-axis direction, and the Z-axis direction, or may be rotatable around the Z-axis direction. By moving support 12, probe 14 can be brought into contact with surface 42a of electrode 42. The movement of support 12 may be controlled by a controller 50.

Probe 14 can contact surface 42a of electrode 42. Probe 14 may be attached to a probe card 15. In this embodiment, a plurality of probes 14 are attached to probe card 15. The number of probes 14 may be two or more, may be 100 or more, or may be 1000 or less. A size of a tip of probe 14 may be not less than 100 nm and not more than 100 μm. Probe 14 includes a material having high thermal conductivity. Examples of such materials include tungsten, rhenium, palladium, platinum, gold, silver, copper or alloys thereof. Probe card 15 is, for example, a wiring substrate. Probe card 15 may be connected to a tester 22 via a wiring 24. Tester 22 inspects one or more electrical characteristics of electronic device W. Tester 22 provides an input voltage to probe 14 and receives an output signal from probe 14 via wiring 24. Tester 22 may include an amplifier for signal amplification and a pulse generator for signal synchronization in addition to a power supply.

Temperature adjusting device 16 adjusts at least one of a temperature of surface 42a of electrode 42 and a temperature of probe 14 such that the temperature of surface 42a of electrode 42 and the temperature of probe 14 are different from each other. In this embodiment, temperature adjusting device 16 adjusts the temperature of probe 14. Temperature adjusting device 16 may be connected to support 12. This allows support 12 and temperature adjusting device 16 to move relative to probe 14 simultaneously. Temperature adjusting device 16 may comprise a temperature adjusting portion 16a and a heat block 16b connected to temperature adjusting portion 16a. Temperature adjusting portion 16a comprises a heating element, e.g. a heater, or a cooling element, e.g. a Peltier-element. The temperature of temperature adjusting device 16 is different from the temperature of electronic device W. An absolute value of the difference between the temperature of electronic device W and the temperature of temperature adjusting device 16 may be 20 degrees or more. In case temperature adjusting device 16 is a heating device, the temperature of temperature adjusting device 16 may be 40° C. or more and less than 100° C. When the temperature of temperature adjusting device 16 is lower than 100° C., thermal damage to electronic device W is reduced. In case temperature adjusting device 16 is a cooling device, the temperature of temperature adjusting device 16 may be −40° C. or more and 0° C. or less.

Temperature measuring device 18 measures the temperature of surface 42a of electrode 42. Temperature measuring device 18 may comprise a thermographic camera. The spatial resolution of the thermographic camera may be greater than or equal to 1 μm and less than or equal to 100 μm.

Determination device 20 is configured to determine whether a contact state between probe 14 and surface 42a of electrode 42 is good or poor based on a measurement result obtained by temperature measuring device 18. Determination device 20 compares a value related to measurement data received from temperature measuring device 18 with a threshold value, and determines whether the contact state between probe 14 and surface 42a of electrode 42 is good or poor based on a comparison result. The value related to measurement data may be the temperature of surface 42a of electrode 42 or a rate of change of the temperature of surface 42a of electrode 42. When probe 14 heats surface 42a of electrode 42, if the temperature of surface 42a of electrode 42 after a lapse of a predetermined time is equal to or higher than a threshold value, it may be determined that the contact state is good. Alternatively, it may be determined that the contact state is good if the rate of increase in the temperature (the amount of change in temperature with respect to time) of surface 42a of electrode 42 is equal to or greater than a threshold value. When probe 14 cools surface 42a of electrode 42, if the temperature of surface 42a of electrode 42 after a lapse of a predetermined time is equal to or lower than a threshold value, it may be determined that the contact state is good. Alternatively, it may be determined that the contact state is good if the rate of decrease in the temperature (the amount of change in temperature with respect to time) of surface 42a of electrode 42 is equal to or less than a threshold value. Determination device 20 may be a computer connected to temperature measuring device 18.

Inspection apparatus 100 may comprise a first camera 30a, a second camera 30b and a third camera 30c. First camera 30a is disposed above probe 14. Second camera 30b can capture an image of a contact point between probe 14 and surface 42a of electrode 42 from the lateral direction (X-axis direction). Third camera 30c is disposed below probe 14. When support 12 is moved so as to retreat from a region between third camera 30c and probe 14, the tip of probe 14 can be imaged by third camera 30c.

According to inspection apparatus 100 of the present embodiment, probe 14 can be brought into contact with surface 42a of electrode 42 in a state where the temperature of probe 14 and the temperature of surface 42a of electrode 42 are different from each other. If the contact state between probe 14 and surface 42a of electrode 42 is good, the temperature of surface 42a of electrode 42 approaches the temperature of probe 14 due to heat transfer. For example, in a surface 42ag among surfaces 42a shown in FIGS. 2 and 3, since the contact state between probe 14 and surface 42ag of electrode 42 is good, the temperature of surface 42ag of electrode 42 becomes closer to the temperature of probe 14. On the other hand, if the contact state between probe 14 and surface 42a of electrode 42 is poor, the temperature of surface 42a of electrode 42 does not approach the temperature of probe 14. For example, in a surface 42an among surfaces 42a shown in FIGS. 2 and 3, since the contact state between probe 14 and surface 42an of electrode 42 is poor, the temperature of surface 42an of electrode 42 does not change. Therefore, by measuring the temperature of surface 42a of electrode 42, the quality of the contact state between probe 14 and surface 42a of electrode 42 can be determined.

In case temperature measuring device 18 comprises a thermographic camera, the temperature of surface 42a of electrode 42 can be measured in a non-contact manner. In addition, the temperature of each surface 42a of the plurality of electrodes 42 arranged in a wide range can be simultaneously measured.

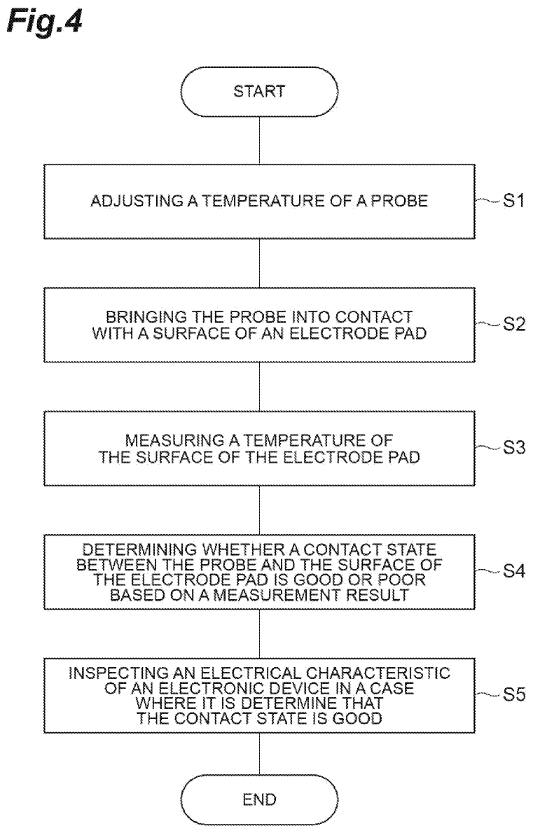

FIG. 4 is a flowchart illustrating an inspecting method for an electronic device according to an embodiment. The inspecting method for the electronic device according to the present embodiment may be performed as follows using the above-described inspection apparatus 100.

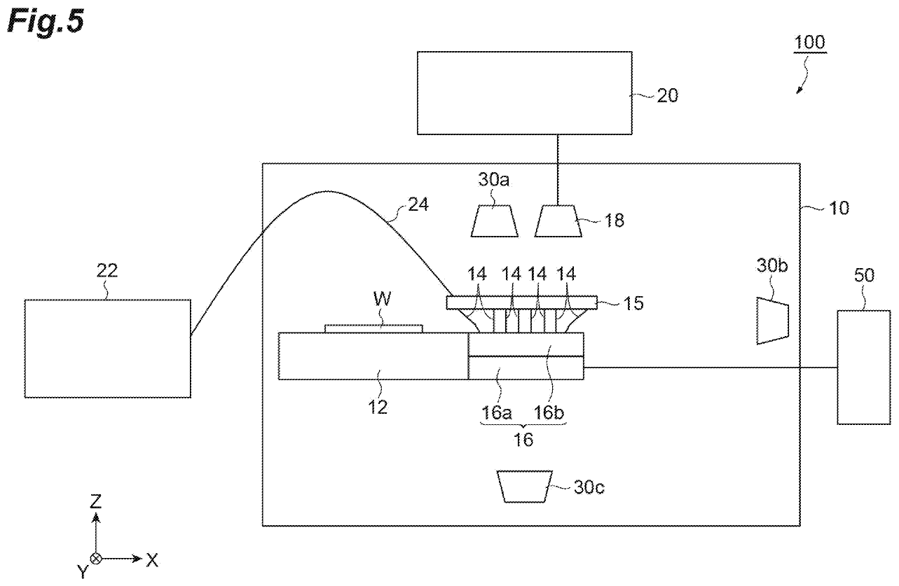

First, a temperature of probe 14 is adjusted (step S1). FIG. 5 schematically illustrates an inspection apparatus for an electronic device according to an embodiment when a temperature of a probe is adjusted. For example, as shown in FIG. 5, the temperature of probe 14 is adjusted by bringing probe 14 into contact with heat block 16b of temperature adjusting device 16. At least one of surface 42a of electrode 42 and probe 14 may be heated. At least one of the temperature of surface 42a of electrode 42 and the temperature of probe 14 may be 40° C. or more and less than 100° C. At least one of surface 42a of electrode 42 and probe 14 may be cooled. At least one of the temperature of surface 42a of electrode 42 and the temperature of probe 14 may be −40° C. or more and 0° C. or less.

After the step S1, probe 14 is brought into contact with surface 42a of electrode 42 (step S2). As shown in FIG. 1, support 12 and temperature adjusting device 16 are moved relative to probe 14 to bring probe 14 into contact with surface 42a of electrode 42.

After the step S2, the temperature of surface 42a of electrode 42 is measured while probe 14 whose temperature is adjusted is in contact with surface 42a of electrode 42 (step S3). Thus, a measurement result of the temperature of surface 42a of electrode 42 is obtained. The measurement is performed by temperature measuring device 18.

After the step S3, based on the measurement result of the temperature of surface 42a of electrode 42, whether the contact state between probe 14 and surface 42a of electrode 42 is good or poor is determined (step S4). The determination is performed by determination device 20.

After the step S4, when the contact state between probe 14 and surface 42a of electrode 42 is determined to be good in the step S4, the electrical characteristic of electronic device W is inspected (step S5).

When the contact state is determined to be poor in the step S4, the step S5 is not performed.

According to the inspection method described above, if the contact state between probe 14 and surface 42a of electrode 42 is good, the temperature of surface 42a of electrode 42 approaches the temperature of probe 14 due to heat transfer. On the other hand, if the contact state between probe 14 and surface 42a of electrode 42 is poor, the temperature of surface 42a of electrode 42 does not approach the temperature of probe 14. Therefore, by measuring the temperature of surface 42a of electrode 42, the quality of the contact state between probe 14 and surface 42a of electrode 42 can be detected.

In the above embodiment, since the step S2 is performed after the step S1, the contact is performed in a state in which the temperature of probe 14 and the temperature of surface 42a of electrode 42 are different from each other. Therefore, after the contact, the quality of the contact state between probe 14 and surface 42a of electrode 42 can be determined in a short time. When the temperature of probe 14 is adjusted, probe 14 may be deformed due to the temperature change. When the step S2 is performed after the step S1, the deformation of probe 14 after the contact can be suppressed.

When the step S5 is performed, the electrical characteristic of electronic device W can be inspected in a state in which the contact state between probe 14 and surface 42a of electrode 42 is good.

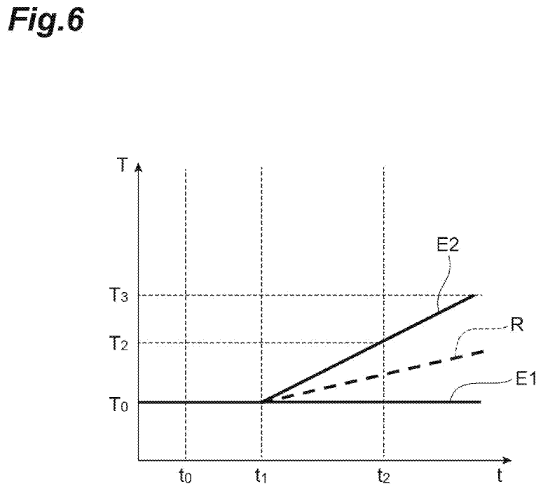

An example of an inspecting method for an electronic device will now be described with reference to FIGS. 1, 4, 5 and 6. FIG. 6 is a graph illustrating an example of the relationship between the temperature of surface of electrode and time. The vertical axis indicates the temperature of surface 42a of electrode 42. The horizontal axis represents time.

Before the step S1, support 12 is aligned so that probe 14 and surface 42a of electrode 42 are in contact with each other. The position of support 12 when probe 14 comes into contact with surface 42a of electrode 42 is stored in a storage unit of controller 50 as a contact position (position shown in FIG. 1).

Next, support 12 is moved in the Z-axis direction and the X-axis direction by controller 50 so that probe 14 faces temperature adjusting device 16. Next, as the step S1, support 12 is moved in the Z-axis direction by controller 50 so that probe 14 is pressed against temperature adjusting device 16 (see FIG. 5).

As shown in FIG. 6, before the step S2, an initial temperature T₀ of surface 42a of electrode 42 is measured by temperature measuring device 18 at time to. When an absolute value of the difference between the initial temperature T₀ and the ambient temperature (the temperature around electronic device W) is within 2 degrees, the step S2 is performed. When the absolute value of the difference between the initial temperature T₀ and the ambient temperature exceeds 2 degrees, the step S2 is not performed.

After the time t₀, the step S2 is started at time t₁. At the time t₁, support 12 is returned to the contact position stored in controller 50 (see FIG. 1). Thus, probe 14 after being heated comes into contact with surface 42a of electrode 42. Since the contact position is stored in controller 50, there is no need to re-align support 12. Therefore, probe 14 separated from temperature adjusting device 16 can be brought into contact with surface 42a of electrode 42 in a short time. Therefore, probe 14 can be brought into contact with surface 42a of electrode 42 before the temperature of probe 14 which is heated decreases.

After the time t₁, the step S3 is started at time t₂. At the time t₂, a temperature T₂ of surface 42a of electrode 42 is measured by temperature measuring device 18. The temperature T₂ is a temperature between a temperature T₃ of probe 14 and the initial temperature T₀ of surface 42a of electrode 42.

After the step S3, the step S4 is started. In the step S4, a rate of increase in the temperature RT of surface 42a of electrode 42 is calculated by the following equation:

RT=(T₂−T₀)/(t₂−t₁)

When the rate of increase in the temperature RT is equal to or greater than a threshold value, it is determined that the contact state is good. When the rate of increase in the temperature RT is less than the threshold value, it is determined that the contact state is poor. In the graph of FIG. 6, a broken line R indicates the threshold value, a solid line E1 indicates a temperature profile in which the contact state is poor, and a solid line E2 indicates a temperature profile in which the contact state is good.

While preferred embodiments of the present disclosure have been described in detail above, the present disclosure is not limited to the above embodiments.

For example, the temperature of surface 42a of electrode 42 may be adjusted by a temperature adjusting device having a configuration similar to that of temperature adjusting device 16. For example, by using the temperature adjusting device for adjusting the temperature of support 12, the temperature of electronic device W can be adjusted. As a result, the temperature of surface 42a of electrode 42 is also adjusted. Alternatively, the ambient temperature (the temperature around electronic device W) may be adjusted by a temperature adjusting device. As a result, the temperature of surface 42a of electrode 42 is also adjusted.

Temperature measuring device 18 may be, for example, a thermometer. By bringing the thermometer into contact with surface 42a of electrode 42, the temperature of surface 42a of electrode 42 can be measured. The temperature of surface 42a of each of the plurality of electrodes 42 may be measured using each of a plurality of thermometers. The thermometer may be combined with a microscope having a lens. In this case, an appropriate spatial resolution is obtained.

Temperature adjusting device 16 may be connected to probe 14 instead of support 12. In this case, the temperature of probe 14 can be adjusted while probe 14 is in contact with surface 42a of electrode 42.

Inspection apparatus 100 may not comprise determination device 20. In this case, an operator may determine whether the contact state between probe 14 and surface 42a of electrode 42 is good or poor based on the measurement result.

The step S2 of the inspection method may be performed simultaneously with the step S1 or may be performed before the step S1. When the step S2 is performed before the step S1, the temperature of probe 14 is adjusted after probe 14 is brought into contact with surface 42a of electrode 42.

It should be understood that the embodiments disclosed herein are illustrative and non-restrictive in every respect. The scope of the present disclosure is defined by the appended claims rather than by the foregoing description, and all changes that come within the meaning and range of equivalency of the claims are intended to be embraced therein.

What is claimed is:

1. An inspection apparatus for an electronic device, the electronic device comprising a substrate and an electrode located on the substrate, the inspection apparatus comprising:
a support to support the electronic device;
a probe to be brought into contact with a surface of the electrode;
a temperature adjusting device configured to adjust at least one of a temperature of the surface of the electrode and a temperature of the probe such that the temperature of the surface of the electrode and the temperature of the probe are different from each other; and
a temperature measuring device configured to measure the temperature of the surface of the electrode.

2. The inspection apparatus according to claim 1, wherein the temperature measuring device comprises a thermographic camera.

3. The inspection apparatus according to claim 1, further comprising:
a determining apparatus configured to determine whether a contact state of the probe and the surface of the electrode is good, based on a measurement result obtained by the temperature measuring device.

4. The inspection apparatus according to claim 1, wherein the temperature adjusting device is configured to adjust the temperature of the probe.

5. The inspection apparatus according to claim 4, wherein the temperature adjusting device is connected to the support.

6. The inspection apparatus according to claim 1, wherein the temperature adjusting device comprises a heating element.

7. The inspection apparatus according to claim 6, wherein a temperature of the temperature adjusting device is 40° C. or more and less than 100° C.

8. The inspection apparatus according to claim 1, wherein the temperature adjusting device comprises a cooling element.

9. The inspection apparatus according to claim 8, wherein a temperature of the temperature adjusting device is −40° C. or more and 0° C. or less.

10. An inspection method for an electronic device, the electronic device comprising a substrate and an electrode located on the substrate, the inspection method comprising:
adjusting at least one of a temperature of a surface of the electrode and a temperature of a probe such that the temperature of the surface of the electrode and the temperature of the probe are different from each other;
bringing the probe into contact with the surface of the electrode;
measuring the temperature of the surface of the electrode after the adjusting and the bringing are performed; and
determining whether a contact state of the probe and the surface of the electrode is good, based on a measurement result of the temperature of the surface of the electrode.

11. The inspection method according to claim 10, wherein after the adjusting is performed, the bringing is performed.

12. The inspection method according to claim 10, further comprising:
inspecting an electrical characteristic of the electronic device in a case where it is determined that the contact state of the probe and the surface of the electrode is good.

13. The inspection method according to claim 10, wherein the temperature of the probe is adjusted in the adjusting.

14. The inspection method according to claim 10, wherein at least one of the surface of the electrode and the probe is heated in the adjusting.

15. The inspection method according to claim 14, wherein the at least one of the temperature of the surface of the electrode and the temperature of the probe is 40° C. or more and less than 100° C. in the adjusting.

16. The inspection method according to claim 10, wherein at least one of the surface of the electrode and the probe is cooled in the adjusting.

17. The inspection method according to claim 16, wherein the at least one of the temperature of the surface of the electrode and the temperature of the probe is −40° C. or more and 0° C. or less in the adjusting.
